(19) United States
(12) Patent Application Publication
(10) Pub. No.: US 2023/0238295 A1
(43) Pub. Date: Jul. 27, 2023

(54) SEMICONDUCTOR DEVICE, METHOD OF MANUFACTURING SEMICONDUCTOR DEVICE, AND POWER CONVERSION APPARATUS

(71) Applicant: Mitsubishi Electric Corporation, Tokyo (JP)

(72) Inventor: Yosuke NAKATA, Tokyo (JP)

(73) Assignee: Mitsubishi Electric Corporation, Tokyo (JP)

(21) Appl. No.: 18/056,479

(22) Filed: Nov. 17, 2022

(30) Foreign Application Priority Data
Jan. 27, 2022 (JP) 2022-010690

(51) Int. Cl. H01L 23/31; H01L 23/29

(52) U.S. Cl. CPC H01L 23/3135; H01L 23/293

(57) ABSTRACT

An object is to provide a technique which suppresses peeling between a sealing resin and a semiconductor element while suppressing a decrease in productivity and an increase in manufacturing cost in a semiconductor device. A semiconductor device includes a semiconductor element, and a sealing resin sealing the semiconductor element. The semiconductor element includes a cell region through which a main current flows, a terminal region provided on an outer peripheral side of the cell region, and a protective film covering an upper surface of an outer peripheral portion of the terminal region. The protective film includes spread portions spreading to outermost ends at four corners of the semiconductor element. The spread portions have a cut section continuous with a cut section of the terminal region, and do not spread to the outermost ends in four sides excluding the four corners of the semiconductor element.

### BACKGROUND OF THE INVENTION

### Field of the Invention

The present disclosure relates to a semiconductor device, a method of manufacturing the semiconductor device, and a power conversion apparatus.

### Description of the Background Art

Conventionally, a semiconductor device in which reliability is improved by covering a semiconductor element with an epoxy resin-based sealing resin has been distributed.

In conventional semiconductor devices, when dicing semiconductor elements from a semiconductor wafer, in order to suppress a decrease in production due to blade clogging or suppress the occurrence of chipping on the outer peripheral portion of the semiconductor elements, a structure in which polyimide is opened on the dicing line is typically adopted. Therefore, there was a portion where no polyimide is provided for several tens of micrometers from the outermost ends of the semiconductor element. When a semiconductor device formed by covering such a semiconductor element with a sealing resin is subjected to a temperature cycle test or the like, peeling occurs between the sealing resin and the semiconductor element at a portion where no polyimide is provided. The peeling develops into the peeling of polyimide of the semiconductor element with the peeling as a starting point, causing a problem of deterioration of the terminal structure of the semiconductor device.

In particular, in a semiconductor device including a semiconductor element using SiC having high Young's modulus as a semiconductor material, the stress caused between the sealing resin and the semiconductor element during temperature cycles increases, highlighting the problem.

For example, International Publication No. 2014/122892 discloses a technique in which, in order to suppress the peeling of the outer peripheral portion of the semiconductor element from the sealing resin, the outer peripheral portion of the semiconductor element is coated with a carbon-based adhesive, after dicing the semiconductor element from the semiconductor wafer.

The technique disclosed in International Publication No. WO 2014/122892, however, the outer peripheral portion of the semiconductor elements is covered with a carbon-based adhesive after dicing semiconductor elements from a semiconductor wafer; therefore, an additional step of forming a carbon-based adhesive layer using a stencil mask is required. As described above, the additional step is required for the semiconductor elements after the completion of the wafer process; therefore, there has been a problem that the manufacturing cost of the semiconductor device increases significantly.

### SUMMARY

An object of the present disclosure is to provide a technique which suppresses peeling between a sealing resin and a semiconductor element while suppressing a decrease in productivity and an increase in manufacturing cost in a semiconductor device.

According to the present disclosure, the semiconductor device includes the semiconductor element and the sealing resin. The semiconductor element is diced into a square shape in top view from the semiconductor wafer 10. The sealing resin seals the semiconductor element. The semiconductor element includes a cell region through which a main current flows, a terminal region provided on an outer peripheral side of the cell region, and a protective film covering an upper surface of an outer peripheral portion of the terminal region. The protective film includes spread portions spreading to the outermost ends at the four corners of the semiconductor element. The spread portions have a cut section continuous with a cut section of the terminal region, and do not spread to the outermost ends in four sides excluding the four corners.

The semiconductor element includes the protective film covering the upper surface of the outer peripheral portion of the terminal region; therefore, the stress applied from the sealing resin can be reduced. Further, the spread portion has the cut section that is continuous with the cut section of the terminal region; therefore, no tolerance, such as alignment tolerance, processing tolerance, and the like occurs between the cut section of the terminal region and the cut section of the spread portion. As a result, the upper surface of the outer peripheral portion of the terminal region is suppressed from coming into contact with the sealing resin at the four corners of the semiconductor element, so that, in the semiconductor element, the stress applied from the sealing resin can further be reduced. As described above, peeling between the sealing resin and the semiconductor element can be suppressed.

Further, the spread portion has the cut section that is continuous with the cut section of the terminal region, and the semiconductor element is diced from the semiconductor wafer after the protective film is formed. This eliminates the need for an additional process for the semiconductor element after the wafer process ends so that an increase in the manufacturing cost of the semiconductor device can be suppressed.

Further, the outermost ends of the four sides of the semiconductor element excluding the four corners are not covered with the protective film; therefore, the semiconductor element can be diced from the semiconductor wafer while preventing clogging of the blade. As a result, a decrease in productivity of semiconductor devices can be suppressed.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1A is a top view of a semiconductor device and FIGS. 1B and 1C are cross-sectional views of a termination structure according to a first embodiment;

FIG. 2 is a graph illustrating a simulation result of the stress reduction effect depending on the width of a spread portion of the semiconductor element provided in the semiconductor device according to the first embodiment;

FIG. 3A is a top view of a semiconductor device and FIGS. 3B and 3C are cross-sectional views of a termination structure according to a modification of the first embodiment;

FIG. 4 is an explanatory diagram for explaining a method of manufacturing the semiconductor device according to the modification of the first embodiment; and

FIG. 5 is a block diagram illustrating a configuration a power conversion system according to a second embodiment.

### DESCRIPTION OF THE PREFERRED EMBODIMENTS

<First Embodiment>

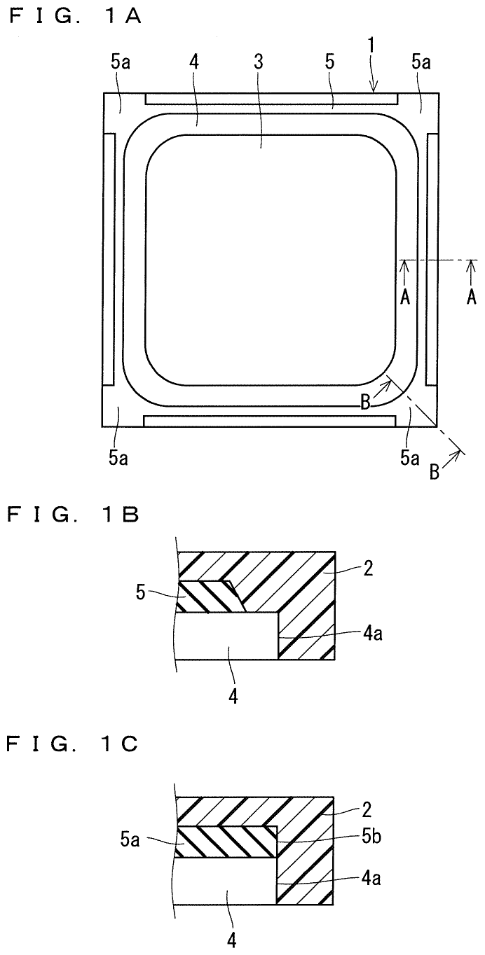

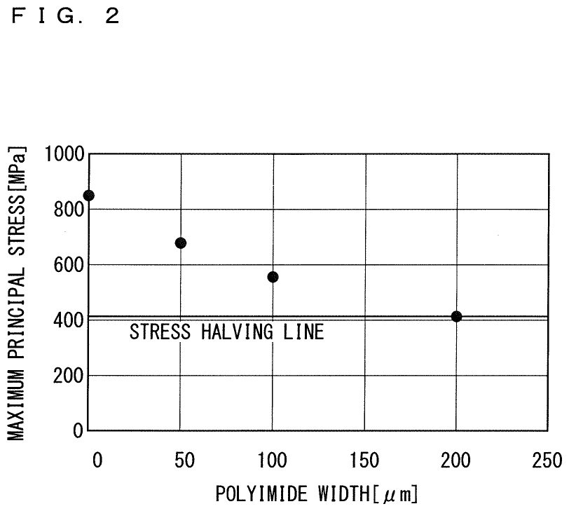

A first embodiment will be described below with reference to the drawings. FIG. 1A is a top view of a semiconductor device according to the first embodiment. FIG. 1B is a cross-sectional view taken along the line A-A of FIG. 1A. FIG. 1C is a cross-sectional view taken along the line B-B of FIG. 1A. In FIG. 1A, the illustration of a sealing resin 2 is omitted for simplicity. FIG. 2 is a graph illustrating a simulation result of the stress reduction effect depending on the width of a spread portion 5a of a semiconductor element 1 provided in the semiconductor device according to the first embodiment.

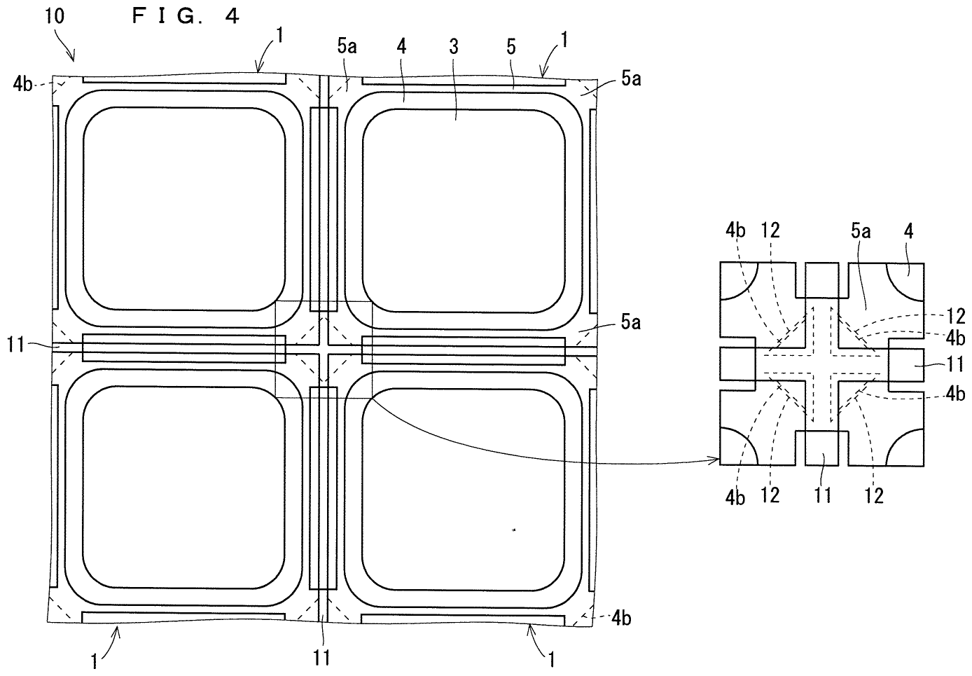

As illustrated in FIGS. 1A, 1B, and 1C, the semiconductor device includes the semiconductor element 1 and the sealing resin 2. The semiconductor element 1 is diced from a semiconductor wafer 10 (see FIG. 4) including a plurality of semiconductor elements 1, and is formed in a square shape in top view. The semiconductor material for the semiconductor element 1 includes, for example, silicon (Si) or silicon carbide (SiC). The sealing resin 2 is made mainly of an epoxy resin, for example, and seals the semiconductor element 1.

The semiconductor element 1 includes a cell region 3 in which a plurality of cells are provided and through which a main current flows, a terminal region 4 provided on the outer peripheral side of the cell region 3, and a protective film 5 covering the upper surface of the outer peripheral portion of the terminal region 4. The cell region 3 is formed in a substantially rectangular shape and is a portion of the semiconductor element 1 excluding the outer peripheral portion. The terminal region 4 is a portion surrounding the cell region 3, that is, the outer peripheral portion of the semiconductor element 1.

The protective film 5 has spread portions 5a spreading to the outermost ends at the four corners of the square-shaped semiconductor element 1. Spread portions 5a have a cut section which is continuous with a cut section 4a of the terminal region 4, and do not spread to the outermost ends in the four sides of the semiconductor element 1 excluding the four corners. Therefore, the upper surface of the termination region 4 is exposed on the four sides of the semiconductor element 1 excluding the four corners.

The protective film 5 is made mainly of polyimide, for example, and is formed by a photomechanical process during a wafer process. For example, a method is adopted in which a photosensitive polyimide precursor solution is applied to the entire semiconductor wafer 10 (see FIG. 4), then it is subjected to pre-baking, an arbitrary pattern is formed by the photomechanical process, and the main baking is performed thereon.

In the case where non-photosensitive polyimide is adopted, a resist is used in the photomechanical process, and an arbitrary pattern is formed by etching through the resist. Accordingly, the thickness of the polyimide can be made uniform by forming the polyimide pattern by coating the entire semiconductor wafer 10 and etching in the photomechanical process. After the polyimide formation process, an arbitrary wafer process is performed and completed, and a dicing step is performed to cut out individual semiconductor elements 1 by dicing the semiconductor wafer 10.

In the dicing step, a disk-shaped grindstone blade is typically used. At this point, polyimide is typically not provided on the dicing line 11 (see FIG. 4) in many cases in order to prevent clogging of the grindstone with polyimide.

In contrast, in the first embodiment, the protective film 5 as a polyimide pattern spreads to the dicing line 11 at the four corners of the semiconductor element 1, and the spread portions 5a are cut together with the terminal region 4 by dicing by the blade.

Spreading of the protective film 5 to the dicing line 11 could cause the clogging of the grindstone of the blade, however, by limiting the area covered by the protective film 5 to the four corners of the semiconductor element 1, clogging of the whetstone of the blade can be suppressed.

Further, the portions of the protective film 5 spreading to the dicing line 11 are cut during dicing, the extended portions 5a have a cut section 5b that is continuous with the cut section 4a of the terminal region 4. Almost no step appears on the continuous cut section, and this allows improvement in the consistency between the cut section 4a of the terminal region 4 and the cut section 5b of the spread portion 5a.

In addition, the protective film 5 is mechanically cut by dicing, the polyimide thickness at the cut section 5b can be made equal to the polyimide thickness of the protective film 5 at other portions. Thus, the four corners of the terminal region 4 can be covered with the protective film 5 having a constant thickness; therefore, the stress caused between the semiconductor element 1 and the sealing resin 2 can be reduced.

Also, the spread portions 5a preferably spread at least 200 μm in the four corners of the semiconductor element 1 to the outermost ends. As illustrated in FIG. 2, the greater the width of the extended portion 5a, the more stress caused at the interface between the protective film 5 and the terminal region 4 is reduced. When the width of the spread portion 5a is 200 pm, the stress can be reduced by half compared to the case of no spread portion 5a (0 μm).

Although not illustrated in FIG. 2, the stress caused at the interface between the protective film 5 and the terminal region 4 tends to be further reduced by increasing the width of the spread portion 5a more than 200 μm. At the interface between the spread portion 5a and the terminal region 4, for example, an oxide film can be provided. By providing the oxide film, improvement in the adhesion between the spread portion 5a and the terminal region 4 is ensured, and this suppresses the spread portion 5a from peeling off from the terminal region 4, improving the reliability of the semiconductor device further.

Further, of the dicing line 11 other than the portions where the spread portions 5a are provided may or may not be provided with an oxide film, which can be arbitrarily selected based on other conditions.

<Modification Example of First Embodiment>

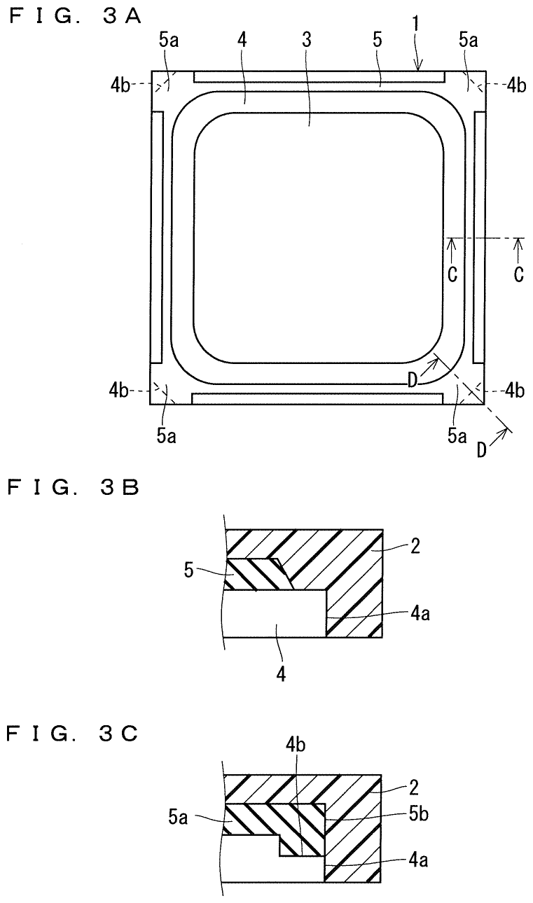

Next, a modification example of the first embodiment will be described. FIG. 3A is a top view of a semiconductor device according to the modification example of the first embodiment. FIG. 3B is a cross-sectional view taken along the line C-C of FIG. 3A.

FIG. 3C is a cross-sectional view taken along the line D-D of FIG. 3A. In FIG. 3A, the illustration of a sealing resin 2 is omitted for simplicity. FIG. 4 is an explanatory diagram for explaining a method of manufacturing a semiconductor device according to a modification example of the first embodiment, and is a top view illustrating part of the semiconductor wafer 10 including a plurality of semiconductor elements 1.

For example, when the semiconductor element 1 is a MOSFET having a trench gate, a trench step is performed to carve grooves for the trench gates in the upper surface of the semiconductor element 1. In the trench step, normally, grooves for trench gates are formed only in the cell region 3. However, in the modification example of the first embodiment, as illustrated in FIGS. 3A, 3B, and 3C, a step portion 4b having a depth equal to that of the trench gate is also provided in the trench step directly below the spread portion 5a in the terminal region 4, that is, in a portion covered with the spread portion 5a in the terminal region 4. As a result, the adhesion between the spread portion 5a and the terminal region 4 is improved, and the peeling of the spread portion 5a from the terminal region 4 can be suppressed more effectively.

The step portions 4b can be provided in a shape in which the four corners of the semiconductor element 1 are chamfered, for example. In this case, the step portion 4b may be provided in a linear chamfered shape, or may be provided in an arbitrary chamfered shape such as a polygonal shape or a curved surface shape along R of the terminal structure.

If the step portion 4b protrudes from the spread portion 5a, the contact between the step portion 4b and the sealing resin 2 may cause cracks in the sealing resin 2, which may become a starting point for peeling of the sealing resin 2. However, such a problem does not occur because the step portion 4b is covered with the spread portion 5a.

As illustrated in FIG. 4, the step portions 4b at the four corners of the semiconductor element 1 are not connected between adjacent semiconductor elements 1 on the semiconductor wafer 10. Therefore, the step pattern forming the step portions 4b is off within a region 12 which is to be completely removed by the blade on the dicing line 11.

In a photomechanical process, a pattern is normally formed on the semiconductor wafer 10 by a plurality of shots, so pattern abnormalities can be suppressed by suppressing trench patterns from overlapping each adjacent shot. Further, the polyimide thickness of the spread portions 5a can be further increased at the four corners of the semiconductor element 1; therefore, the stress can be reduced more effectively.

<Effect>

As described above, the semiconductor device according to the first embodiment includes the semiconductor element 1 diced into a square shape in top view from the semiconductor wafer 10, and the sealing resin 2 sealing the semiconductor element 1, in which the semiconductor element 1 includes the cell region 3 through which a main current flows, the terminal region 4 provided on the outer peripheral side of the cell region 3, and the protective film 5 covering the upper surface of the outer peripheral portion of the terminal region 4, the protective film 5 includes spread portions 5a spreading to the outermost ends at the four corners of the semiconductor element 1, spread portions 5a have a cut section 5b continuous with a cut section 4a of the terminal region 4, and do not spread to the outermost ends in the four sides excluding the four corners.

Therefore, the semiconductor element 1 includes the protective film 5 covering the upper surface of the outer peripheral portion of the terminal region 4; therefore, the stress applied from the sealing resin 2 can be reduced. Further, the spread portion 5a has the cut section 5b that is continuous with the cut section 4a of the terminal region 4; therefore, no tolerance, such as alignment tolerance, processing tolerance, and the like occurs between the cut section 4a of the terminal region 4 and the cut section 5b of the spread portion 5a. As a result, the upper surface of the outer peripheral portion of the terminal region 4 is suppressed from coming into contact with the sealing resin 2 at the four corners of the semiconductor element 1, so that, in the semiconductor element 1, the stress applied from the sealing resin 2 can further be reduced. As described above, peeling between the sealing resin 2 and the semiconductor element 1 can be suppressed. Consequently, improvement in the durability of the semiconductor device is ensured. Further, the spread portion 5a has the cut section 5b that is continuous with the cut section 4a of the terminal region 4, and the semiconductor element 1 is diced from the semiconductor wafer 10 after the protective film 5 is formed. This eliminates the need for an additional process for the semiconductor element 1 after the wafer process ends so that an increase in the manufacturing cost of the semiconductor device can be suppressed.

Further, the outermost ends of the four sides of the semiconductor element 1 excluding the four corners are not covered with the protective film 5; therefore, the semiconductor element 1 can be diced from the semiconductor wafer 10 while preventing clogging of the blade. As a result, a decrease in productivity of semiconductor devices can be suppressed.

Moreover, the protective film 5 contains polyimide. A material that can be formed by a conventional wafer process is used so that the protective film 5 can be easily formed.

Also, the spread portions 5a spread at least 200 μm to the outermost ends at the four corners of the semiconductor element 1; therefore, the stress applied from the sealing resin 2 can be sufficiently reduced. As a result, even when the protective film 5 is mainly composed of photosensitive polyimide having half the peel strength of non-photosensitive polyimide, peeling of the protective film 5 can be suppressed.

A trench gate is provided in the cell region 3, and a step portion 4b having a depth equal to that of the trench gate is provided in a portion of the terminal region 4 covered with the spread portion 5a.

Therefore, the adhesion between the spread portion 5a and the terminal region 4 can be improved, thereby suppressing the peeling of the spread portion 5a from the terminal region 4 more effectively.

Also, the semiconductor material of the semiconductor element 1 is SiC. A problem has conventionally arisen in a semiconductor device including a semiconductor element using SiC having high Young's modulus that the stress during temperature cycles generated between the sealing resin and the semiconductor element increases causes deterioration of the terminal structure of the semiconductor device. In the semiconductor device according to the present embodiment, meanwhile, peeling between the sealing resin 2 and the semiconductor element 1 can be suppressed so that deterioration of the terminal structure of the semiconductor device can be suppressed.

Further, the step portion 4b is formed in a step pattern extending to a portion of the semiconductor wafer 10 overlapping with the dicing line 11, and the step pattern does not overlap with the step pattern of the other adjacent semiconductor elements 1 on the semiconductor wafer 10; therefore, the step pattern can be formed for each shot. Consequently, formation of useless patterns on the dicing line 11 can be avoided.

In addition, the cut section 5b of the spread portion 5a and the cut section 4a of the terminal region 4 are formed by dicing with the blade so that the clogging of the blade can be suppressed. This will be described in detail.

In a conventional manner, when the outer peripheral portion of a semiconductor element is entirely covered with a protective film and the semiconductor element covered with the protective film is diced with a blade, the blade is clogged with dust from the protective film. In contrast, in the first embodiment, by limiting the portions covered with protective film 5 to the four corners of semiconductor element 1, the reduction in the time and frequency of dicing leading to clogging is ensured. In addition, during the dicing of the portions not covered with the protective film 5, dust from the protective film 5 is likely to come off. Accordingly, the effect of suppressing clogging of the blade is obtained.

<Second Embodiment>

In a second embodiment, the semiconductor device according to the above-described first embodiment is applied to a power conversion apparatus. Although the application of the semiconductor device according to the first embodiment is not limited to a specific power conversion apparatus, hereinafter, as the second embodiment, a case where the semiconductor device according to the first embodiment is applied to a three-phase inverter will be described.

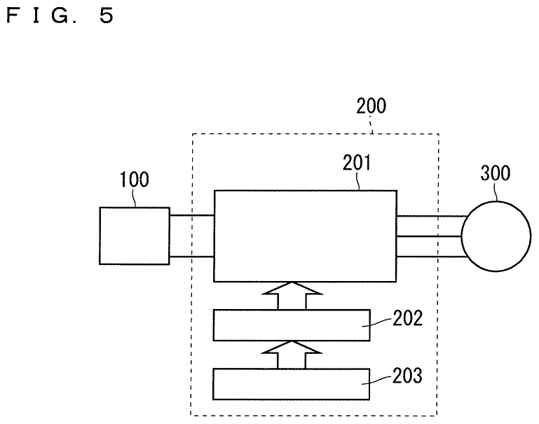

FIG. 5 is a block diagram illustrating a configuration of a power conversion system to which a power conversion apparatus according to the second embodiment is applied.

The power conversion system illustrated in FIG. 5 includes a power supply 100, a power conversion apparatus 200, and a load 300. The power supply 100 is a DC power supply and supplies DC power to the power conversion apparatus 200. The power supply 100 can be configured with various components, for example, the configuration thereof may include a DC system, a solar cell, and a storage battery, or include a rectifier circuit connected to an AC system or an AC/DC converter. Further, the power supply 100 may be configured by a DC/DC converter that converts the DC power output from the DC system into a predetermined power.

The power conversion apparatus 200 is a three-phase inverter connected between the power supply 100 and the load 300, which converts the DC power supplied from the power supply 100 into AC power and supplies AC power to the load 300. As illustrated in FIG. 5, the power conversion apparatus 200 includes a main conversion circuit 201 that converts DC power into AC power and outputs thereof, and a drive circuit 202 that outputs a drive signal for driving each switching element of the main conversion circuit 201, and a control circuit 203 that outputs a control signal for controlling the drive circuit 202 to the drive circuit 202.

The load 300 is a three-phase electric motor driven by AC power supplied from the power conversion apparatus 200. The load 300 is not limited to a specific application, and is an electric motor mounted on various electric devices. For example, the load 300 is used as an electric motor for a hybrid vehicle, an electric vehicle, a railroad vehicle, an elevator, or an air conditioning apparatus.

Hereinafter, the detailed description is made on the power conversion apparatus 200. The main conversion circuit 201 includes a switching element (not illustrated) and a freewheeling diode (not illustrated), and by switching the switching element, the DC power supplied from the power supply 100 is converted into AC power and supplied to the load 300. There are various specific circuit configurations of the main conversion circuit 201, and the main conversion circuit 201 according to the second embodiment is a two-level three-phase full bridge circuit, and has six switching elements and six freewheeling diodes each of which is anti-parallel with the respective switching elements. For at least any of either each switching element or each freewheeling diode of the main conversion circuit 201, the semiconductor device according to the first embodiment described above is applied. Each of the two switching elements connected in series of the six switching elements constitutes an upper and lower arm, and each upper and lower arm constitutes each phase (U phase, V phase, W phase) of the full bridge circuit. Then, the output terminal of each upper and lower arm, that is, the three output terminals of the main conversion circuit 201 are connected to the load 300.

The drive circuit 202 generates a drive signal for driving the switching element of the main conversion circuit 201 and supplies the drive signal to the control electrode of the switching element of the main conversion circuit 201. Specifically, in response to the control signal from the control circuit 203 described later, a drive signal for turning on the switching element and a drive signal for turning off the switching element are output to the control electrode of each switching element. When the switching element is kept in the ON state, the drive signal is a voltage signal (ON signal) equal to or higher than a threshold voltage of the switching element, and when the switching element is kept in the OFF state, the drive signal is a voltage signal (OFF signal) equal to or lower than the threshold voltage of the switching element.

The control circuit 203 controls the switching elements of the main conversion circuit 201 so that the desired power is supplied to the load 300. Specifically, the time (ON time) for each switching element of the main conversion circuit 201 to be in the ON state is calculated based on the power to be supplied to the load 300. For example, the main conversion circuit 201 is controlled by PWM control that modulates the ON time of the switching element according to the voltage to be output. Then, a control command (control signal) is output to the drive circuit provided in the driving circuit 202 so that an ON signal is output to the switching element supposed to be turned on at each time point and an OFF signal is output to the switching element supposed to be turned off. The drive circuit 202 outputs an ON signal or an OFF signal as a drive signal to the control electrode of each switching element according to the control signal.

The semiconductor device according to the first embodiment is applied as the switching element of the main converter circuit 201 in the power conversion apparatus 200 according to the second embodiment, improvement in durability can be realized.

Although in the present embodiment, the semiconductor device according to the first embodiment is applied to the two-level three-phase inverter has been described, the semiconductor device according to the first embodiment is not limited thereto, and can be applied to various power conversion apparatuses. Although in the second embodiment, a two-level power conversion apparatus is adopted, a three-level or multi-level power conversion apparatus may also be adoptable, and when power is supplied to a single-phase load, the semiconductor device according to the first embodiment may also be adopted to a single-phase inverter. Further, when supplying power to a DC load or the like, the semiconductor device according to the first embodiment is adoptable to the DC/DC converter or the AC/DC converter.

Further, the power conversion apparatus to which the semiconductor device according to the first embodiment is applied is not limited to the case where the above-mentioned load is an electric motor, the power conversion apparatus can be applied to the case where a load is a power supply device for an electric discharge machine, a laser machine, an induction heating cooker, or a contactless power supply system, further applied to the case where a load is a power conditioner for a solar power generation system and a power storage systems, for example.

The embodiments can be combined, appropriately modified or omitted.

While the disclosure has been illustrated and described in detail, the foregoing description is in all aspects illustrative and not restrictive. It is therefore understood that numerous modifications and variations can be devised without departing from the scope of the invention.

What is claimed is:

1. A semiconductor device comprising:
a semiconductor element diced into a square shape in top view from a semiconductor wafer; and
a sealing resin sealing the semiconductor element, wherein
the semiconductor element includes a cell region through which a main current flows, a terminal region provided on an outer peripheral side of the cell region, and a protective film covering an upper surface of an outer peripheral portion of the terminal region,
the protective film includes spread portions spreading to outermost ends at four corners of the semiconductor element, and
the spread portions have a cut section continuous with a cut section of the terminal region, and do not spread to the outermost ends in four sides excluding the four corners of the semiconductor element.

2. The semiconductor device according to claim 1, wherein
the protective film contains polyimide.

3. The semiconductor device according to claim 1, wherein
the spread portions spread at least 200 μm in the four corners of the semiconductor element to the outermost ends.

4. The semiconductor device according to claim 1, wherein
a trench gate is provided in the cell region, and
a step portion having a depth equal to that of the trench gate is provided in a portion of the terminal region covered with the spread portion.

5. The semiconductor device according to claim 1, wherein
a semiconductor material of the semiconductor element is SiC.

6. A method of manufacturing the semiconductor device according to claim 4, wherein
the step portion is formed in a step pattern extending to a portion of the semiconductor wafer overlapping with a dicing line, and
the step pattern does not overlap with a step pattern of other adjacent semiconductor elements on the semiconductor wafer.

7. The method of manufacturing the semiconductor device according to claim 1, wherein
the cut section of the spread portion and the cut section of the terminal region are formed by dicing with a blade.

8. A power conversion apparatus comprising:
a conversion circuit including a semiconductor device according to claim 1, and configured to convert and output input power;
a drive circuit configured to output a drive signal for driving the semiconductor device to the semiconductor device; and
a control circuit configured to output a control signal for controlling the drive circuit to the drive circuit.
